(19) United States
(12) Patent Application Publication
(10) Pub. No.: US 2025/0079400 A1
(43) Pub. Date: Mar. 6, 2025

(54) UNSINGULATED SEMICONDUCTOR PACKAGE

(71) Applicant: Western Digital Technologies, Inc., San Jose, CA (US)

(72) Inventors: Yangming Liu, Shanghai (CN); ZiJing Yu, Shanghai (CN); Feng Zhu, Shanghai (CN); Jing He, Shanghai (CN); Hengxu Yu, Shanghai (CN)

(21) Appl. No.: 18/456,906

(22) Filed: Aug. 28, 2023

(51) Int. Cl. H01L 25/065; H01L 21/78; H01L 23/00; H01L 23/31; H01L 23/498; H01L 23/538; H01L 25/00; H10B 80/00

(52) U.S. Cl. CPC H01L 25/0655; H01L 21/78; H01L 23/3128; H01L 23/49816; H01L 23/5386; H01L 24/48; H01L 25/50; H10B 80/00; H01L 2224/48225

(57) ABSTRACT

An unsingulated semiconductor package includes multiple integrated circuits provided on a single substrate segment and encapsulated by a single cover. The unsingulated semiconductor package is mounted on a PCB of a computing component to increase the capacity and performance capabilities of the computing component without occupying additional space on the PCB.

### BACKGROUND

A computing component typically includes a number of semiconductor packages mounted on a printed circuit board (PCB). For example, a solid state drive (SSD) typically includes a number of individual NAND memory packages mounted on the PCB.

Capabilities of the computing component may be increased by adding additional semiconductor packages. For example, in order to increase the capacity of an SSD, additional NAND memory packages are mounted to the PCB. However, as additional semiconductor packages are added, the size of the computing component increases.

Accordingly, it would be beneficial to increase the capabilities of a computing component without increasing a size of the computing component and without increasing the number of semiconductor packages that are mounted on the PCB of the computing component.

### SUMMARY

The present application describes an unsingulated semiconductor package. In an example, the unsingulated semiconductor package includes multiple integrated circuits provided on a single substrate segment. The unsingulated semiconductor package may be mounted on or otherwise coupled to a printed circuit board (PCB) of a computing component. When compared with current solutions in which multiple singulated semiconductor packages are mounted on the PCB of the computing component, the unsingulated semiconductor package described herein increases the capacity/performance capabilities of the computing component by at least fifty percent without occupying additional space on the PCB.

Accordingly, examples of the present disclosure describe a computing component that includes PCB and an unsingulated semiconductor package electrically coupled to the PCB. In an example, the unsingulated semiconductor package includes a plurality of integrated circuits provided on an unsingulated substrate segment. The unsingulated substrate segment may include a first substrate segment, a second substrate segment adjacent the first substrate segment and an unsingulated area provided between the first substrate segment and the second substrate segment.

In another example, the present disclosure describes a method that includes assembling a plurality of semiconductor packages on a substrate. In an example, each semiconductor package includes a plurality of integrated circuits attached to a substrate segment. Additionally, each substrate segment is defined by a plurality of saw streets and includes a first singulation area, a second singulation area and an unsingulated area. In an example, a first integrated circuit of the plurality of integrated circuits is adjacent the first singulation area, a second integrated circuit of the plurality of integrated circuits is adjacent the second singulation area and a third integrated circuit of the plurality of integrated circuits is placed on the unsingulated area between the first integrated circuit and the second integrated circuit. A semiconductor package singulation process is used to separate each of the plurality of semiconductor packages along each of the plurality of saw streets.

In yet another example, the present disclosure describes a memory device that includes a substrate having at least one saw street that separates the substrate into first and second adjacent sections. A plurality of memory dies is provided on a first surface of the substrate. In an example, the plurality of memory dies includes a first memory die mounted on the first section, a second memory die mounted on the second section, and a third memory die mounted in an area between the first and second sections and spanning the at least one saw street. The memory device also includes means for electrically connecting the plurality of memory dies to the substrate, means for encapsulating the plurality of memory dies, and external electrical connection means attached to a second surface of the substrate opposing the first surface of the substrate, the external electrical connection means allowing the memory device to be connected to host device.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a substrate strip having an array of semiconductor packages according to current solutions.

FIG. 1B illustrates a singulated semiconductor package that has been separated from the substrate strip of FIG. 1A by a semiconductor package singulation process according to an example.

FIG. 1C illustrates a side view of the singulated semiconductor package of FIG. 1B according to an example.

FIG. 1D illustrates multiple singulated semiconductor packages being mounted on a PCB according to an example.

FIG. 2A illustrates a substrate strip having an array of semiconductor packages with each semiconductor package having multiple integrated circuits according to an example.

FIG. 2B illustrates an unsingulated semiconductor package that has been separated from the substrate strip of FIG. 2A by a semiconductor package singulation process according to an example.

FIG. 2C illustrates a side view of the unsingulated semiconductor package of FIG. 2B according to an example.

FIG. 2D illustrates the unsingulated semiconductor package of FIG. 2C being mounted on a PCB according to an example.

FIG. 3 illustrates a method for manufacturing an unsingulated semiconductor package according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Computing components typically include a number of semiconductor packages that are surface mounted or are otherwise coupled to a printed circuit board (PCB). Typically, each semiconductor package includes a single integrated circuit. The number and type of semiconductor packages included with a particular computing component may vary depending on the intended use and/or desired performance capabilities of the computing component.

For example, a memory device, such as a solid state drive (SSD), may include up to sixteen (or more) individual NAND memory packages that are mounted on a PCB. Further, each NAND memory package may include a single memory die (or stack of memory dies).

During a semiconductor package assembly process, an integrated circuit (e.g., a memory die) is attached to a designated area on a substrate panel or substrate strip. Bond wires may be used to electrically couple the integrated circuit to the substrate and/or to interconnects associated with the semiconductor package. A molding compound and/or a lid typically encapsulates the bond wires and the integrated circuit. One or more solder balls may also be coupled to a bottom side of the substrate.

Once the semiconductor package has been assembled, the semiconductor package undergoes a semiconductor package singulation process. During the semiconductor package singulation process, a saw (or other cutting tool, such as a laser) is used to separate each semiconductor package from other semiconductor packages that were assembled on the substrate panel or substrate strip.

For example, the substrate panel or substrate strip includes various saw lines or saw streets that are arranged in a grid pattern. During the semiconductor package singulation process, the saw cuts along each of the saw streets to create a singulated semiconductor package. Each singulated semiconductor package may then be tested and/or individually mounted to the PCB.

This process helps ensure a high yield of usable semiconductor packages and increases the efficiency and cost-effectiveness of semiconductor package production. However, saw streets occupy large areas on the substrate strip. In some examples, each saw street has a width between 0.25 millimeters (mm) and 1.3 mm. As such, a lot of space on the substrate strip is wasted.

To address the above, the present application describes an unsingulated semiconductor package that includes multiple independent integrated circuits (e.g., semiconductor dies, NAND memory dies, stacks of NAND memory dies, dynamic random access memory (DRAM) dies, application-specific integrated circuits (ASICs)) on a single substrate segment. In an example, at least one integrated circuit of the unsingulated semiconductor package is attached to or placed on (e.g., during a die attach stage of a semiconductor package assembly process) an area of the substrate segment that would typically be reserved for, is otherwise identified as a singulation area and/or contains a saw street.

During a semiconductor package singulation process, the saw street, or the area of the substrate segment on which the integrated circuit is placed, is skipped. As such, an unsingulated semiconductor package having multiple integrated circuits is created. Once the unsingulated semiconductor package has been separated from other unsingulated semiconductor packages, each unsingulated semiconductor package may be tested and electrically and/or communicatively coupled to a PCB. In some examples, the performance capabilities (e.g., storage capacity) of the unsingulated semiconductor package may be fifty percent greater when compared with current singulated semiconductor packages while occupying the same amount of space on the PCB.

Accordingly, many technical benefits may be realized including, but not limited to, increasing the capabilities of a computing component while maintaining space requirements and enabling semiconductor packages to be more densely arranged when compared with current solutions which may reduce command response times and power requirements. Additionally, the present disclosure avoids the unnecessary waste of materials by reducing the number of times the substrate strip is cut while also simplifying the semiconductor packaging testing process (by enabling the integrated circuits of the unsingulated semiconductor package to be tested at the same time) and by simplifying the computing component assembly process (by enabling multiple integrated circuits of the unsingulated semiconductor package to be mounted on the PCB during a single step).

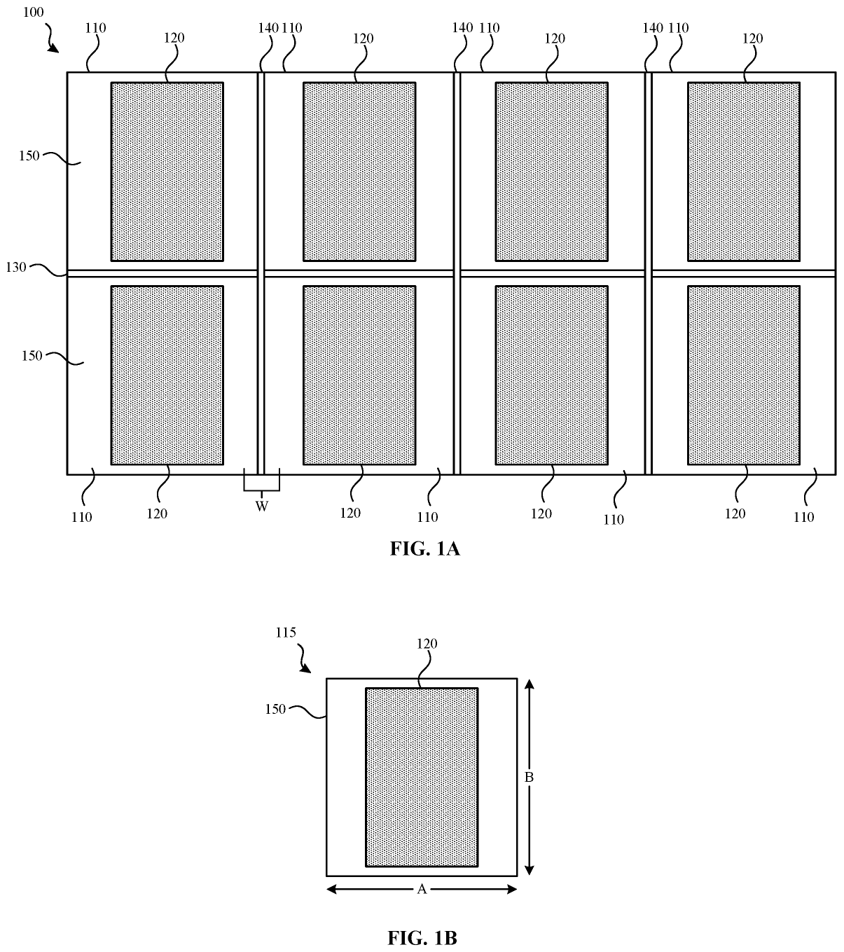

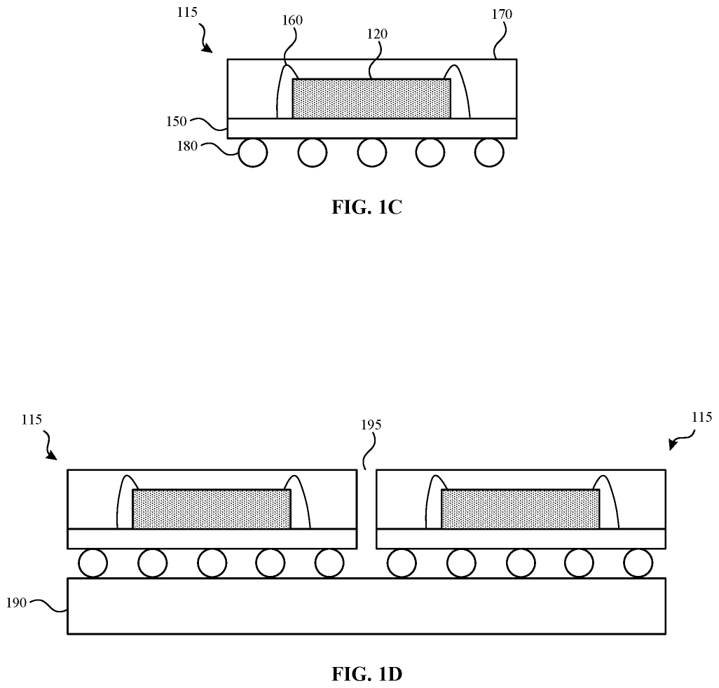

These and other examples will be shown and described in greater detail with respect to FIG. 1A-FIG. 3.

FIG. 1A illustrates a substrate strip 100 having an array of semiconductor packages 110 according to current solutions. In the example shown, the substrate strip 100 includes eight semiconductor packages 110. Each semiconductor package 110 includes an integrated circuit 120. Although eight semiconductor packages 110 are shown, the substrate strip 100 may include any number of semiconductor packages 110.

Each semiconductor package 110 is assembled using any suitable semiconductor package assembly process. For example, once the integrated circuits 120 are fabricated, each integrated circuit 120 is attached to a specified area on the substrate strip 100. In the example shown in FIG. 1A, a first integrated circuit is attached to a first area on the substrate strip 100, a second integrated circuit is attached to a second area on the substrate strip 100 and so on.

Each area on the substrate strip 100 is defined by one or more saw streets. For example, the substrate strip 100 includes a horizontal saw street 130 and multiple vertical saw streets 140. As shown, the saw streets are arranged in a grid pattern and are used to designate various areas, or substrate segments 150, of the substrate strip 100. In an example, each saw street includes, defines or is otherwise associated with a width “W”. The width of each saw street is typically between 0.25 millimeters (mm) and 1.3 mm.

Once the integrated circuits 120 have been attached to the various areas of the substrate strip 100, a wire bonding process may be used to communicatively couple integrated circuit 120 to its respective substrate segment 150. A molding compound may then be used to encapsulate the integrated circuit 120 and the bond wires. Solder balls may then be attached to, or otherwise formed on, a bottom surface of each substrate segment 150.

Once the semiconductor package assembly process is complete, a semiconductor package singulation process separates each of the semiconductor packages 110 into singulated semiconductor packages. For example, a saw forms cuts along the horizontal saw street 130 and each of the vertical saw streets 140 to separate each semiconductor package 110 from the other semiconductor packages 110.

FIG. 1B illustrates a singulated semiconductor package 115 that has been separated from the substrate strip 100 of FIG. 1A by a semiconductor package singulation process according to an example. As shown in FIG. 1B, the singulated semiconductor package 115 includes a single integrated circuit 120 on a substrate segment 150. In an example, the singulated semiconductor package 115 has a width of “A” and a length of “B”. As such, the semiconductor package 110 has an area of A*B.

FIG. 1C illustrates a side view of the singulated semiconductor package 115 of FIG. 1B according to an example. As previously discussed, the singulated semiconductor package 115 includes an integrated circuit 120 mounted on the substrate segment 150. Bond wires 160 electrically and/or communicatively couple the integrated circuit 120 to the substrate segment 150 and/or to various solder balls 180 provided on a bottom surface of the substrate segment 150. A molding compound or a cover 170 may encapsulate the integrated circuit 120 and the bond wires 160.

FIG. 1D illustrates multiple singulated semiconductor packages 115 being mounted on a PCB 190 according to an example. As shown, each singulated semiconductor package 115 is separately mounted to the PCB 190. In an example, the singulated semiconductor packages 115 occupy an area on the PCB 190 equivalent to (2A+Space)*B where “Space” (represented by reference number 195) is an amount of space between each singulated semiconductor package 115 on the PCB 190.

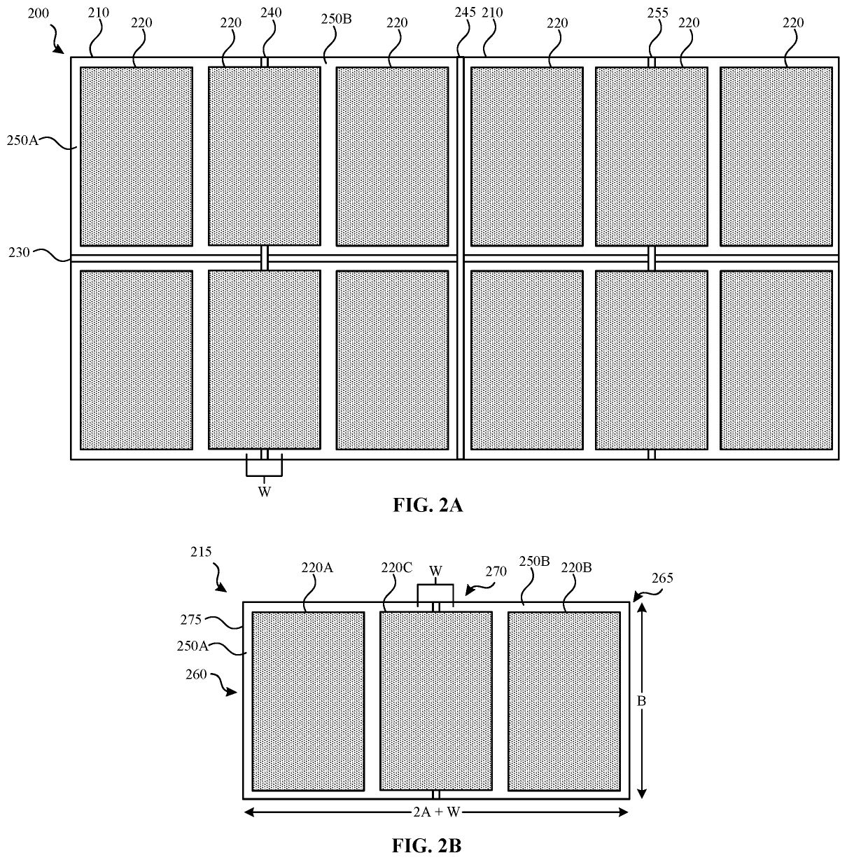

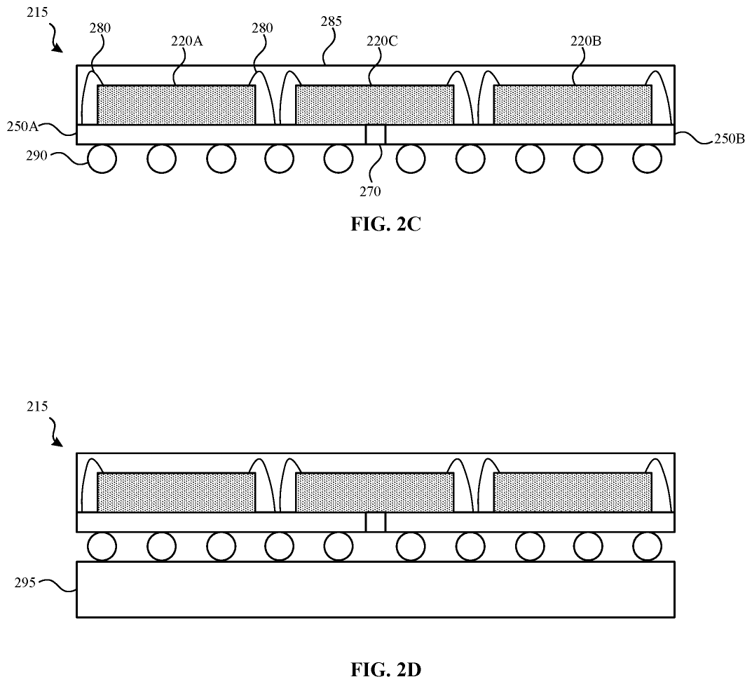

FIG. 2A illustrates a substrate strip 200 having an array of semiconductor packages 210 with each semiconductor package 210 having a multiple integrated circuits 220 according to an example. In the example shown, the substrate strip 200 includes four semiconductor packages 210. Although four semiconductor packages 210 are shown, the substrate strip 200 may include any number of semiconductor packages 210.

In contrast to the semiconductor packages 110 shown and described with respect to FIG. 1A that include a single integrated circuit 120, each semiconductor package 210 includes multiple integrated circuits 220. For example, each semiconductor package 210 includes three different/individual integrated circuits 220. Although three integrated circuits 220 are shown, the semiconductor package 210 may have fewer than three (e.g., two) integrated circuits 220 or more than three integrated circuits 220.

In an example, the substrate strip 200 includes various areas or substrate segments. For example, the substrate strip 200 may include a first substrate segment 250A and a second substrate segment 250B. Further, each area or substrate segment may be defined by various saw streets. For example, the substrate strip 200 includes a horizontal saw street 230 and multiple vertical saw streets (e.g., a first vertical saw street 240, a second vertical saw street 245 and a third vertical saw street 255). Although a specific number of saw streets are shown, the substrate strip 200 may include any number of horizontal and vertical saw streets.

Each saw street has a width “W”. In an example, the width of each saw street is between 0.25 mm and 1.3 mm, although other widths may be used. For purposes of explanation, each saw street may be identified or otherwise referred to as a singulation area. As used herein, a singulation area is an area or portion of the substrate strip 200 that includes a saw street or is identified as an area that would typically include a saw street (e.g., the area includes or would include a saw street if the integrated circuits 220 were placed one per substrate segment such as shown in FIG. 1A). In an example and as will be described in greater detail below, a singulation area, or a saw street, may either be cut during a semiconductor package singulation process or may be skipped during the semiconductor package singulation process.

In an example, each semiconductor package 210 is assembled using any suitable semiconductor package assembly process. For example, once the integrated circuits 220 are fabricated, the integrated circuits 220 are placed and/or arranged on the semiconductor strip 200. In an example, a first integrated circuit 220 is placed adjacent a first singulation area or saw street, a second integrated circuit 220 is placed adjacent a second singulation area or saw street and a third integrated circuit 220 is placed on an unsingulated area provided between the first integrated circuit 220 and the second integrated circuit 220.

In an example, the unsingulated area is an area on the substrate strip 200 that includes a saw street (e.g., the first vertical saw street 240 or the third vertical saw street 255) or is otherwise identified as a singulation area (e.g., a saw street may or may not be present on the singulated area but will be skipped or otherwise not cut during a semiconductor package singulation process). In an example, two or more adjacent substrate segments may be combined or otherwise remain unsingulated after a semiconductor package singulation process has occurred. For example, the first substrate segment 250A and the second substrate segment 250B may remain combined or otherwise not separated (e.g., unsingulated) during the semiconductor package singulation process.

Once the integrated circuits 220 have been attached to the various areas of the substrate strip 200, a wire bonding process may be used to communicatively couple each integrated circuit 220 of the semiconductor package 210 to its respective substrate segment(s). A molding compound may then be used to encapsulate the integrated circuits 220 and the bond wires. Solder balls may then be attached to, or otherwise formed on, a bottom surface of the substrate strip 200.

Once the semiconductor package assembly process is complete, a semiconductor package singulation process separates each of the semiconductor packages 220 into separate “unsingulated” semiconductor packages. For example, a semiconductor package singulation process causes a saw (or other cutting mechanism) to form cuts along the horizontal saw street 230 and the second vertical saw street 245. The semiconductor package singulation process omits or skips cutting along the first vertical saw street 240 and the third vertical saw street 255.

FIG. 2B illustrates an unsingulated semiconductor package 215 according to an example. The unsingulated semiconductor package 215 is created in response to a semiconductor package singulation process being performed on the substrate strip 200 shown and described with respect to FIG. 2A.

In an example, the unsingulated semiconductor package 215 includes multiple separate/independent integrated circuits 220 on an unsingulated substrate segment 275. For example, the unsingulated substrate segment 275 includes two adjacent substrate segments (e.g., substrate segment 250A and substrate segment 250B) and at least one saw street (e.g., a portion of the first vertical saw street 240 (FIG. 2A)) that was skipped or otherwise omitted from a cutting process during the semiconductor package singulation process.

For example, the unsingulated semiconductor package 215 includes a first integrated circuit 220A, a second integrated circuit 220B and a third integrated circuit 220C. In an example each of the integrated circuits 220 is a NAND memory die or a stack of NAND memory dies. In another example, the integrated circuits are any type of semiconductor dies or chips such as, for example, DRAM dies, ASICs and the like.

In an example, the first integrated circuit 220A is adjacent a first singulation area 260 (e.g., an area that included a saw street or was otherwise sawed through during the semiconductor package singulation process) and the second integrated circuit 220B is adjacent a second singulation area 265. Additionally, the third integrated circuit 220C is provided on an unsingulated area 270.

In an example, the unsingulated area 270 may include a saw street (e.g., at least a portion of the first vertical saw street 240) that was skipped or otherwise not sawed through during the semiconductor package singulation process. In an example, the saw street that is included as part of the unsingulated area 270 may be visible or otherwise present on the substrate strip 200. In another example, the saw street itself may not be visible or present but the unsingulated area 270 may be identified as an area in which a saw street (or a singulation area) would typically be present if the integrated circuits 220 were arranged in the manner shown in FIG. 1A. In another example, the unsingulated area 270 may include an area between two adjacent semiconductor segments (e.g., semiconductor segment 250A and semiconductor segment 250B).

In an example, the unsingulated semiconductor package 215 width of “2A +W” where “A” is the width of the first semiconductor segment 250A and the width of the second semiconductor segment 250B and where “W” is the width of the saw street (e.g., the first vertical saw street 240) that was skipped or omitted from the semiconductor package singulation process. The unsingulated semiconductor package 215 also has a length of “B”. As such, the unsingulated semiconductor package 215 has an area of (2A+W)*B.

FIG. 2C illustrates a side view of the unsingulated semiconductor package 215 of FIG. 2B according to an example. In an example, the unsingulated semiconductor package 215 includes multiple integrated circuits on an unsingulated semiconductor segment. For example, a first integrated circuit 220A is attached to or mounted on a first substrate segment 250A, a second integrated circuit 220B is attached to or mounted on a second substrate segment 250B and a third integrated circuit 220C is attached to or mounted on an unsingulated area 270 between the first integrated circuit 220A and the second integrated circuit 220B.

In an example, the unsingulated area 270 includes at least a portion of the first substrate segment 250A, at least a portion of the second substrate segment 250B and a saw street (or other area that is identified as a singulation area) that will be skipped or otherwise will not be cut during the semiconductor package singulation process.

FIG. 2C also illustrates that each integrated circuit includes bond wires 280 that electrically and/or communicatively couple the integrated circuits to the substrate and/or to various solder balls 290 provided on a bottom surface of the substrate. A molding compound, a lid or a cover 285 may encapsulate integrated circuits and the bond wires 280.

FIG. 2D illustrates the unsingulated semiconductor package 215 being mounted on a PCB 295 according to an example. When compared with the semiconductor packages 110 shown in FIG. 1D, the unsingulated semiconductor package 215 increases capacity by at least fifty percent while occupying the same or substantially the same area on the PCB 295.

For example and as previously described, the unsingulated semiconductor package 215 may occupy an area of (2A+W)*B while two singulated semiconductor packages 115 may occupy an area of (2A+Space)*B. Depending on how “Space” compares with “W”, the unsingulated semiconductor package 215 may occupy the same or similar area on the PCB 295 as two singulated semiconductor packages 115, but with at least a fifty percent increase in capacity (e.g., due to the extra integrated circuit).

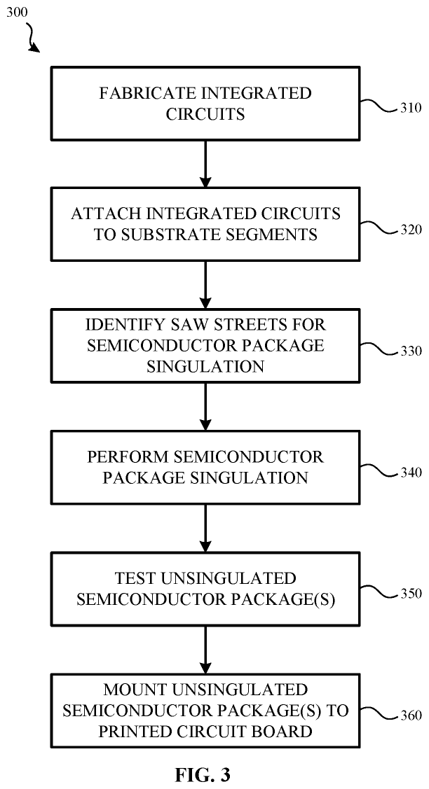

FIG. 3 illustrates a method 300 for manufacturing an unsingulated semiconductor package according to an example. In an example, the method 300 may be used to manufacture the unsingulated semiconductor package 215 shown and described with respect to FIG. 2B-FIG. 2C. In another example, the method 300 may be used to manufacture a computing component that utilizes one or more unsingulated semiconductor packages.

The method 300 begins when integrated circuits are fabricated (310). In an example, the integrated circuits are fabricated using one or more fabrication techniques/processes. Once the integrated circuits have been fabricated, the integrated circuits are attached (320) to one or more substrate segments of a substrate strip. In an example, the substrate strip includes a number of saw streets or segmentation areas. The saw streets or the segmentation areas may be arranged in a grid or other pattern and may define one or more of the substrate segments.

During placement of the integrated circuits, a first integrated circuit may be placed on the substrate strip (or the substrate segment) adjacent a first segmentation area. Likewise, a second integrated circuit may be placed on the substrate strip (or the substrate segment) adjacent a second segmentation area. Additionally, a third integrated circuit may be placed on the substrate strip (or the substrate segment) on an area this is identified as an unsingulated area.

In an example, the unsingulated area may be between the first integrated circuit and the second integrated circuit. The unsingulated area may (or may not) include a saw street or may otherwise be identified as a potential singulation area. However, as will be described below, even if the unsingulated area includes a saw street (or was otherwise identified as a singulation area), the saw street will not be cut (e.g., the saw street will be skipped) during a subsequent semiconductor package singulation process. In addition to placement/attachment of the integrated circuits on the substrate strip, operation 320 may also include a wire bonding process, an encapsulation process and/or a solder ball attachment process.

When the semiconductor packages have been assembled, saw streets that will be used for a semiconductor package singulation process are identified (330). In an example, the saw streets that are identified for cutting are the saw streets on which an integrated circuit has not been placed. In another example and as part of a semiconductor package singulation process, one or more saw streets may be selected for cutting/sawing while other saw streets may be skipped or otherwise not selected for cutting/sawing. In yet another example, saw streets on which an integrated circuit is placed during operation 320 may be identified as a saw street to be skipped during the semiconductor singulation process.

A semiconductor package singulation process may then be performed (340). It should be appreciated that the semiconductor package singulation process of the present disclosure requires fewer cuts to produce higher density semiconductor packages when compared with current solutions. For example, because integrated circuits may be placed on or otherwise associated with some saw streets, those saw streets are skipped during the semiconductor package singulation process. Therefore, higher density semiconductor packages are produced with fewer cutting steps/processes.

Once the semiconductor packages have been separated, the unsingulated semiconductor packages are tested (350). In an example, because the unsingulated semiconductor packages include multiple integrated circuits, the testing process may be simplified when compared with current solutions. For example, a single testing process may test two (or more) integrated circuits at once when compared with current solutions in which a single integrated circuit in a semiconductor package is tested.

Upon passing the testing process, the unsingulated semiconductor package may be mounted (360) on a PCB. As with the singulation and testing processes, the mounting process is also an improvement over current solutions. For example, a single mounting process using the unsingulated semiconductor package enables two (or more) integrated circuits to be attached to the PCB versus a single integrated circuit that are typically included in current semiconductor packages.

Based on the above, examples of the present disclosure describe a computing component, comprising: a printed circuit board (PCB); and an unsingulated semiconductor package electrically coupled to the PCB, the unsingulated semiconductor package comprising: a plurality of integrated circuits provided on an unsingulated substrate segment, the unsingulated substrate segment comprising: a first substrate segment; a second substrate segment adjacent the first substrate segment; and an unsingulated area provided between the first substrate segment and the second substrate segment. In an example, the unsingulated substrate segment is associated with a plurality of saw streets. In an example, each of the plurality of saw streets have a width between 0.25 millimeters (mm) and 1.3 mm. In an example, a first integrated circuit of the plurality of integrated circuits is provided on the first substrate segment; a second integrated circuit of the plurality of integrated circuits is provided on the second substrate segment; and a third integrated circuit of the plurality of integrated circuits is provided on the unsingulated area. In an example, the unsingulated area is associated with a saw street that was skipped during a semiconductor package singulation process. In an example, each of the plurality of integrated circuits include one or more semiconductor dies. In an example, the plurality of integrated circuits are encapsulated by a single cover. In an example, the unsingulated semiconductor package is separated from a plurality of other unsingulated semiconductor packages during a semiconductor package singulation process.

Examples also describe a method, comprising: assembling a plurality of semiconductor packages on a substrate, wherein: each semiconductor package includes a plurality of integrated circuits attached to a substrate segment; and each substrate segment is defined by a plurality of saw streets and includes a first singulation area, a second singulation area and an unsingulated area, wherein a first integrated circuit of the plurality of integrated circuits is adjacent the first singulation area, a second integrated circuit of the plurality of integrated circuits is adjacent the second singulation area and a third integrated circuit of the plurality of integrated circuits is placed on the unsingulated area between the first integrated circuit and the second integrated circuit; and performing a semiconductor package singulation process to separate each of the plurality of semiconductor packages along each of the plurality of saw streets. In an example, the method also includes mounting at least one semiconductor package of the plurality of semiconductor packages on a printed circuit board (PCB). In an example, the unsingulated area is associated with a saw street that was skipped during the semiconductor package singulation process. In an example, the saw street has a width between 0.25 millimeters (mm) and 1.3 mm. In an example, each of the plurality of integrated circuits include one or more semiconductor dies.

Examples also describe a memory device, comprising: a substrate having at least one saw street that separates the substrate into first and second adjacent sections; a plurality of memory dies provided on a first surface of the substrate, wherein the plurality of memory dies includes a first memory die mounted on the first section, a second memory die mounted on the second section, and a third memory die mounted in an area between the first and second sections and spanning the at least one saw street; means for electrically connecting the plurality of memory dies to the substrate; means for encapsulating the plurality of memory dies; and external electrical connection means attached to a second surface of the substrate opposing the first surface of the substrate, the external electrical connection means allowing the memory device to be connected to host device. In an example, the electrically connecting means comprise bond wires. In an example, the at least one saw street has a width between 0.25 millimeters (mm) and 1.3 mm. In an example, the memory dies comprise NAND dies. In an example, the at least one saw street is a saw street that was skipped during a semiconductor package singulation process. In an example, the encapsulating means comprises a mold compound. In an example, the external electrical connection means comprises solder balls.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A computing component, comprising:
a printed circuit board (PCB); and
an unsingulated semiconductor package electrically coupled to the PCB, the unsingulated semiconductor package comprising:
a plurality of integrated circuits provided on an unsingulated substrate segment, the unsingulated substrate segment comprising:
a first substrate segment;
a second substrate segment adjacent the first substrate segment; and
an unsingulated area provided between the first substrate segment and the second substrate segment.

2. The computing component of claim 1, wherein the unsingulated substrate segment is associated with a plurality of saw streets.

3. The computing component of claim 2, wherein each of the plurality of saw streets have a width between 0.25 millimeters (mm) and 1.3 mm.

4. The computing component of claim 1, wherein:
a first integrated circuit of the plurality of integrated circuits is provided on the first substrate segment;
a second integrated circuit of the plurality of integrated circuits is provided on the second substrate segment; and
a third integrated circuit of the plurality of integrated circuits is provided on the unsingulated area.

5. The computing component of claim 1, wherein the unsingulated area is associated with a saw street that was skipped during a semiconductor package singulation process.

6. The computing component of claim 1, wherein each of the plurality of integrated circuits include one or more semiconductor dies.

7. The computing component of claim 1, wherein the plurality of integrated circuits are encapsulated by a single cover.

8. The computing component of claim 1, wherein the unsingulated semiconductor package is separated from a plurality of other unsingulated semiconductor packages during a semiconductor package singulation process.

9. A method, comprising:
assembling a plurality of semiconductor packages on a substrate, wherein:
each semiconductor package includes a plurality of integrated circuits attached to a substrate segment; and
each substrate segment is defined by a plurality of saw streets and includes a first singulation area, a second singulation area and an unsingulated area, wherein a first integrated circuit of the plurality of integrated circuits is adjacent the first singulation area, a second integrated circuit of the plurality of integrated circuits is adjacent the second singulation area and a third integrated circuit of the plurality of integrated circuits is placed on the unsingulated area between the first integrated circuit and the second integrated circuit; and
performing a semiconductor package singulation process to separate each of the plurality of semiconductor packages along each of the plurality of saw streets.

10. The method of claim 9, further comprising mounting at least one semiconductor package of the plurality of semiconductor packages on a printed circuit board (PCB).

11. The method of claim 9, wherein the unsingulated area is associated with a saw street that was skipped during the semiconductor package singulation process.

12. The method of claim 11, wherein the saw street has a width between 0.25 millimeters (mm) and 1.3 mm.

13. The method of claim 9, wherein each of the plurality of integrated circuits include one or more semiconductor dies.

14. A memory device, comprising:
a substrate having at least one saw street that separates the substrate into first and second adjacent sections;
a plurality of memory dies provided on a first surface of the substrate, wherein the plurality of memory dies includes a first memory die mounted on the first section, a second memory die mounted on the second section, and a third memory die mounted in an area between the first and second sections and spanning the at least one saw street;
means for electrically connecting the plurality of memory dies to the substrate;
means for encapsulating the plurality of memory dies; and
external electrical connection means attached to a second surface of the substrate opposing the first surface of the substrate, the external electrical connection means allowing the memory device to be connected to host device.

15. The memory device of claim 14, wherein the electrically connecting means comprise bond wires.

16. The memory device of claim 14, wherein the at least one saw street has a width between 0.25 millimeters (mm) and 1.3 mm.

17. The memory device of claim 14, wherein the memory dies comprise NAND dies.

18. The memory device of claim 14, wherein the at least one saw street is a saw street that was skipped during a semiconductor package singulation process.

19. The memory device of claim 14, wherein the encapsulating means comprises a mold compound.

20. The memory device of claim 14, wherein the external electrical connection means comprises solder balls.
